(19) United States
(12) Patent Application Publication
(10) Pub. No.: US 2007/0127608 A1
(43) Pub. Date: Jun. 7, 2007

(54) BLIND INTERFERENCE MITIGATION IN A DIGITAL RECEIVER

(76) Inventors: Jacob Scheim, Pardes Hanna (IL); Assaf Ben-Yishai, Ra'anana (IL); Amir Ingber, Petah Tikva (IL); Evgeny Yakhnich, Hadera (IL)

Correspondence Address: ZARETSKY & ASSOCIATES PC, 8753 W. RUNION DR., PEORIA, AZ, 85382-6412, US

(21) Appl. No.: 11/465,443

(22) Filed: Aug. 17, 2006

Related U.S. Application Data
(60) Provisional application No. 60/748,118, filed on Dec. 6, 2005.

(51) Int. Cl. H03D 1/04

(52) U.S. Cl. 375/346

(57) ABSTRACT

A novel and useful apparatus for and method of Gaussian Minimum Shift Keying (GMSK) single antenna interference cancellation (SAIC) for use in a digital receiver. The invention comprises an interference mitigation module that treats the problem of GMSK SAIC in a blind manner. The interference mitigation mechanism is operative to compensate for the co-channel interference added in the communications channel which is subject to multipath propagation and fading, receiver filter and any pre-channel estimation filtering. The interference mitigation module takes advantage of the spatial diversity making up multiple branches of the received signal. The branches comprise the in-phase and quadrature elements of the received signal, the sampling phases if over sampling is applied (i.e. T/m sampling) and/or multiple antennas. The invention utilizes the spatial diversity of these multiple representations of the received signal and combines (i.e. collapses) the information in the plurality of branches into a single branch that is input to the equalizer.

### REFERENCE TO PRIORITY APPLICATION

This application claims priority under 35 U.S.C. § 119(e) to U.S. Provisional Application Ser. No. 60/748,118, filed Dec. 6, 2005, entitled “GMSK Single Antenna Interference Cancellation for Digital Receivers,” incorporated herein by reference in its entirety.

### FIELD OF THE INVENTION

The present invention relates generally to wireless communication systems and more particularly relates to an apparatus and method of single antenna interference suppression for use in digital receivers.

### BACKGROUND OF THE INVENTION

In recent years, the world has witnessed explosive growth in the demand for wireless communications and it is predicted that this demand will increase in the future. This growth is both in the number of subscribers, and in the bandwidth and services provided to each subscriber. As an example of the increased use of cellular services, the number of GSM subscribers around the world alone was recently reported to exceed 2.2 billion and is growing constantly. One in three people around the world now have a mobile phone and in some developed markets mobile penetration has already approached 100%. It is predicted that by 2010 there will be over 5 billion individual wireless subscribers worldwide.

In some countries, the number of cellular subscribers already exceeds the number of fixed line telephone installations. In many cases, the revenues from mobile services exceeds that for fixed line services even though the amount of traffic generated through mobile phones is less than in fixed networks.

Other related wireless technologies have experienced growth similar to that of cellular. For example, cordless telephony, two way radio trunking systems, paging (one way and two way), messaging, wireless local area networks (WLANs), wireless local loops (WLLs), WiMAX and Ultra Wideband (UWB) based MANs.

Currently, the majority of users subscribe to digital cellular networks. Almost all new cellular handsets sold to customers are based on digital technology, typically third generation digital technology. Currently, fourth generation digital networks are being designed and tested which will be able to support data packet networks and much higher data rates. The first generation analog systems comprise the well known protocols AMPS, TACS, etc. The digital systems comprise GSM/GPRS/EGPRS, TDMA (IS-136), CDMA (IS-95), UMTS (WCDMA), etc. Future fourth generation cellular services are intended to provide mobile data at rates of 100 Mbps or more.

One of the side effects of the growing number of subscribers is an increase in the interference in cellular networks. Stray signals, or signals intentionally introduced by frequency reuse methods, can interfere with the proper transmission and reception of voice and data signals which causes decreased capacity. The constant increase in the deployment of cellular networks increases both the levels of background interference and interference due to co-channel transmission. For typical cell layouts, the major source of noise and interference experienced by GSM communication devices when the network is supporting a non-trivial number of users is due to co-channel and/or adjacent channel interference. Such noise sources arise from nearby devices transmitting on or near the same channel as the desired signal, or from adjacent channel interference, such as noise arising on the desired channel due to spectral leakage.

In GSM networks, frequency reuse in nearby cells causes a mobile terminal to receive in its downlink channel both the designated transmission from its base station, and an interfering signal from a nearby base station. An equivalent effect also occurs in the uplink channel at the base stations receivers. This is referred to as co-channel interference and is becoming more and more influential with the increase in the number of users per each cell and with the decrease in cell size. The effects of co-channel interference can severely damage the receiver performance and can result in decreasing the capacity of the entire network.

A diagram illustrating an example cellular network including a plurality of EDGE transmitters and receivers and GMSK transmitters generating co-channel interference is shown in FIG. 1. The example cellular network, generally referenced 10, comprise EDGE transmitters 12, GMSK transmitters 14 and a GMSK receiver 16. The plurality of EDGE transmitters and GSM transmitters generate co-channel interference at the EDGE receiver 16.

This interference from these noise sources is sensed in both mobile terminals and base stations. In areas with dense cellular utilization a severe degradation in network performance is reported due to this effect. Furthermore, cellular operators with low network bandwidth are forced to lower the reuse factor in their networks which further increases the rate of channel co-transmissions. The problem of co-channel transmissions poses a disjoint problem for both the receiver at the base station and the receiver at the mobile station.

For the base station the co-channel interference problem is considered easier to handle than in the case of mobile terminals. One reason for that is that the higher cost of base station equipment permits the insertion of complex receivers to combat the sensed interferences. The receivers in the base station (1) incorporate algorithms with higher levels of complexity, (2) can have higher power consumption, etc. Another reason the co-channel interference problem is considered simpler in the base station than in the case of mobile terminals is that the base station can utilize better antennas or arrays of antennas referred to as smart antennas to help deal with the problem of co-channel interference. Although smart antennas will affect the cost of the base station, its main impact is in the physical size of the antenna. Due to the size of the smart antenna, its use with mobile, portable cellular equipment is severely limited. Its use with base stations, however, is not limited considering the static relatively large sized antennas permitted for base stations. The size of base station antennas is practically unbounded and therefore the usage of smart phased array antennas is possible. This enables the use of receive diversity techniques with multi user separation capability.

In the mobile terminal, on the other hand, both complexity and size are crucial factors in the applicability of interference combating solutions. The applicability of interference combating solutions is usually determined by aspects of size, power consumption and cost. Solutions consisting of complex algorithms typically increase the computational complexity and memory usage at the receiver resulting in increased power consumption and silicon real estate. The former reduces the applicability of the solution for a mobile terminal while the latest increases the terminal cost, both of which are unfavorable. Further, complex antennas are usually less applicable at mobile terminals due to physical limits affecting the size and placement of antennas over the mobile terminal and the associated increased cost. The tiny size of pocket-sized mobile terminals today substantially limits the expected effectiveness in choosing a smart antenna solution, leaving them for base station applications only.

Therefore, in order for cellular networks to remain effective, there is renewed interest in simple interference reduction solutions that are applicable with a single antenna input. The term single antenna interference cancellation (SAIC) has been coined which refers to interference reduction solutions applicable with a single antenna input. Recently the term SAIC has evolved into the term downlink advanced receiver performance (DARP). Both these terms represent a class of new algorithms intended to reduce the effect of co-channel interference at mobile receivers. Recently, there is great interest in developing an effective interference reduction solution with regards to GSM networks especially for voice applications. This is because the coverage of GSM services is expected to increase greatly and it is expected that GSM transmissions from neighboring cells will be appear as co-channel interference.

Numerous SAIC solutions have been suggested. These prior art solutions to the problem can generally be divided into two classes: (1) joint solutions and (2) blind detection. The first class is based on joint detection in which both the signal and the interferer are demodulated at the receiver. Joint solutions can yield improved performance but are usually less appealing due to the following reasons: (a) they are usually computationally expensive, (b) they demand information on the timing of the interferer (e.g., the joint approach requires a certain level of synchronization for the cellular network which is not trivial to provide) and its training sequence, (c) they usually require a replacement of the standard channel equalizer by a special type of equalizer referred to as a joint equalizer.

The second class refers to solutions based on blind detection which model an interferer as noise with a complex statistical nature. Blind solutions are usually less computationally expensive. An advantage of blind solutions is that they do not require a priori knowledge about the timing and training sequence of the interferer signal. In addition, they can conform to the current trend in the cellular communication industry which prefers solutions that can be implemented as an add-on unit inserted into a conventional receiver.

Many prior art interference cancellation techniques have focused on adjacent channel suppression which uses several filtering operations to suppress the frequencies of the received signal that are not also occupied by the desired signal. Co-channel interference techniques, such as joint demodulation, generally require joint channel estimation methods to provide a joint determination of the desired and co-channel interfering signal channel impulse responses. Given known training sequences, all the co-channel interferers can be estimated jointly. Joint demodulation, however, consumes a large number of MIPS processing, which limits the number of equalization parameters that can be used efficiently. Moreover, classical joint demodulation only addresses one co-channel interferer, and does not address adjacent channel interference.

Thus, there is a need for a Single Antenna Interference Cancellation (SAIC) solution for reducing the effect of co-channel interfering signals that does not require a priori knowledge of the interferers, is suitable for implementation in mobile handsets, is relatively simple to implement, does not have high MIPS consumption and does not significantly increase cost.

### SUMMARY OF THE INVENTION

Accordingly, the present invention provides a novel and useful apparatus for and method of Gaussian Minimum Shift Keying (GMSK) single antenna interference cancellation (SAIC) for use in a digital receiver. The invention comprises an interference mitigation module that functions to treat the problem of GMSK SAIC in a blind manner. The resulting receiver with the interference mitigation module incorporated therein exhibits high performance gain and low computational complexity while overcoming the problems of the prior art.

The interference mitigation mechanism of the present invention is suitable for use in many types of communication receivers, e.g., digital receivers. A receiver incorporating the interference mitigation mechanism of the present invention may be coupled to a wide range of channels and is particularly useful in improving the performance in GSM and other types of cellular communications systems, including but not limited to, Global Systems for Mobile communications (GSM), Code Division Multiple Access (CDMA, Time Division Multiple Access (TDMA), etc. Other wireless communications systems that can benefit from the present invention include paging communication devices, cordless telephones, telemetry systems, etc. These types of channels are typically characterized by fading and multipath propagation with rapidly changing channel impulse response. The interference mitigation mechanism of the present invention is operative to compensate for the co-channel interference added in the communications channel (e.g., cellular channel) which is also subject to multipath propagation and fading, receiver filter and any pre-channel estimation filtering.

To aid in illustrating the principles of the present invention, the apparatus and method are presented in the context of a GSM EDGE mobile station. It is not intended that the scope of the invention be limited to the examples presented herein. One skilled in the art can apply the principles of the present invention to numerous other types of communication systems as well (wireless and non-wireless) without departing from the scope of the invention.

The present invention provides a novel class of algorithms for Downlink Advanced Receiver Performance (DARP) receivers. The proposed approach is based on a novel interference mitigation module that takes advantage of the spatial diversity making up multiple branches of the received signal. The branches comprise the in-phase and quadrature elements of the received signal, the sampling phases if over sampling is applied (i.e. T/m sampling) and multiple antennas. The invention utilizes the spatial diversity of these multiple representations of the signal and combines (i.e. collapses) the information in the plurality of branches into a single branch that is input to the equalizer.

This document presents a DARP receiver capable of handling GMSK SAIC in a blind fashion wherein the interfering signals comprise GMSK modulated signals. Note that throughout this document the term GMSK denotes both GSM and GPRS modulation schemes. The solution presented by the present invention is blind and is therefore sufficiently robust for use in many well-known testing scenarios. It is noted that the blind receiver approach taken by the present invention is capable of improving the performance of a reference receiver by 7 dB for a TU50 GSM test scenario. In addition, substantial improvements are observed for the case of unsynchronized network testing scenarios while the proposed algorithm does not reduce performance in conventional testing scenarios. Furthermore, the interference mitigation mechanism of the present invention enables receivers to meet the new standard demand for DARP receivers.

Many aspects of the invention described herein may be constructed as software objects that execute in embedded devices as firmware, software objects that execute as part of a software application on either an embedded or non-embedded computer system running a real-time operating system such as WinCE, Symbian, OSE, Embedded LINUX, etc., or non-real time operating systems such as Windows, UNIX, LINUX, etc., or as soft core realized HDL circuits embodied in an Application Specific Integrated Circuit (ASIC) or Field Programmable Gate Array (FPGA), or as functionally equivalent discrete hardware components.

There is thus provided in accordance with the invention, an apparatus for interference mitigation in a digital receiver comprising a multiple input multiple output (MIMO) filter operative to generate a plurality D of diversity branches as a function of a spatially diverse input signal and a plurality of parameter vectors, each parameter vector associated with one of the diversity branches and a parameter calculation module operative to generate the plurality of parameter vectors against an optimization criterion having predetermined constraints.

There is also provided in accordance with the invention, an apparatus for interference mitigation in a digital receiver comprising a multiple input multiple output (MIMO) filter operative to generate a plurality D of diversity branches as a function of a spatially diverse input signal and a plurality of parameter vectors, each parameter vector associated with one of the diversity branches, a parameter calculation module operative to generate the plurality of parameter vectors against an optimization criterion having predetermined constraints and a diversity combiner operative to combine the D diversity branches into a single branch.

There is further provided in accordance with the invention, an apparatus for interference mitigation in a digital receiver comprising a multiple input multiple output (MIMO) filter operative to generate a plurality D of diversity branches as a function of a spatially diverse input signal and a plurality of parameter vectors, each parameter vector associated with one of the diversity branches, a parameter calculation module operative to generate the plurality of parameter vectors against an optimization criterion having predetermined constraints and a spatial equalizer operative to generate a plurality of soft values as a function of the plurality D of diversity branches.

There is also provided in accordance with the invention, an apparatus for interference mitigation in a digital receiver comprising a multiple input multiple output (MIMO) filter operative to generate a plurality D of diversity branches as a function of a spatially diverse input signal and a plurality of parameter vectors, each parameter vector associated with one of the diversity branches, a parameter calculation module operative to generate the plurality of parameter vectors against an optimization criterion having predetermined constraints, and to generate a channel impulse response for each the diversity branch, a diversity combiner operative to combine the D diversity branches into a single branch and to combine the D channel impulse responses into a single channel impulse response and an equalizer operative to remove intersymbol interference introduced by the channel from the single branch and to generate a plurality of soft values therefrom.

There is further provided in accordance with the invention, a computer program product characterized by that upon loading it into computer memory an interference mitigation process is executed, the computer program product comprising a computer usable medium having computer usable program code for mitigating interference in a digital receiver, the computer program product including, computer usable program code for implementing a multiple input multiple output (MIMO) filter operative to generate a plurality D of diversity branches as a function of a spatially diverse input signal and a plurality of parameter vectors, each parameter vector associated with one of the diversity branches, computer usable program code for generating the plurality of parameter vectors against an optimization criterion having predetermined constraints and computer usable program code for implementing a diversity combiner operative to combine the D diversity branches into a single branch.

There is also provided in accordance with the invention, a radio receiver coupled to a single antenna comprising a radio frequency (RF) receiver front end circuit for receiving a radio signal transmitted over a channel and downconverting the received radio signal to a baseband signal, the received radio signal comprising an information component and an interference component, a demodulator adapted to demodulate the baseband signal in accordance with the modulation scheme used to generate the transmitted radio signal, an interference mitigation module comprising a multiple input multiple output (MIMO) filter operative to generate a plurality D of diversity branches as a function of a spatially diverse input signal and a plurality of parameter vectors, each parameter vector associated with one of the diversity branches, a parameter calculation module operative to generate the plurality of parameter vectors and to generate the plurality of channel impulse responses corresponding to each the diversity branch against an optimization criterion having predetermined constraints, a diversity combiner operative to combine the D diversity branches into a single branch and to combine the D channel impulse responses into a single channel impulse response, an equalizer adapted to remove intersymbol interference introduced by the channel impulse response from the single branch and to generate a plurality of soft values therefrom and a decoder adapted to decode the output of the equalizer to generate output data therefrom.

### BRIEF DESCRIPTION OF THE DRAWINGS

The invention is herein described, by way of example only, with reference to the accompanying drawings, wherein:

FIG. 1 is a diagram illustrating an example cellular network including a plurality of EDGE and GMSK transmitters generating co-channel interference;

FIG. 2 is a block diagram illustrating an example communications system constructed in accordance with the present invention;

FIG. 3 is a block diagram illustrating the signal flow of a typical GSM receiver demodulator;

FIG. 4 is a block diagram illustrating the interference mitigation module and equalizer of the present invention;

FIG. 5 is a block diagram illustrating an example SAIC interference mitigation module and equalizer of the present invention;

FIG. 6 is a block diagram illustrating the MIMO filter of the present invention;

FIG. 7 is a block diagram illustrating the MISO filter of the present invention;

FIG. 8 is a block diagram illustrating the parameter calculation metric of the present invention for a single branch;

FIG. 9 is a block diagram illustrating the MISO filter with over sampling and multiple antennas constructed in accordance with the present invention;

FIG. 10 is a block diagram illustrating the diversity combiner of the present invention in more detail;

FIG. 11 is a graph illustrating simulation results for a receiver implementing the interference mitigation mechanism of the present invention with respect to a conventional receiver;

FIG. 12 is a block diagram illustrating the processing blocks of a GSM EGPRS mobile station in more detail including RF, baseband and signal processing blocks; and

FIG. 13 is a block diagram illustrating an example computer processing system adapted to implement the interference mitigation mechanism of the present invention.

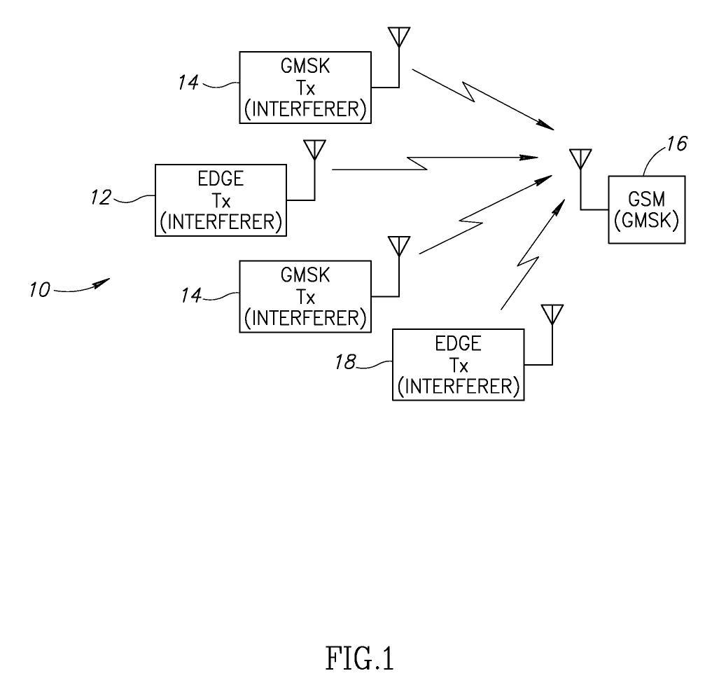

### DETAILED DESCRIPTION OF THE INVENTION

### Notation Used Throughout

The following notation is used throughout this document.

| Term | Definition |
|---|---|
| 8PSK | 8 Phase Shift Keying |
| AMPS | Advanced Mobile Telephone System |
| AMR | Adaptive Multi Rate |
| ASIC | Application Specific Integrated Circuit |
| AWGN | Additive White Gaussian Noise |
| BPSK | Binary Phase Shift Keying |
| CDMA | Code Division Multiple Access |
| CD-ROM | Compact Disc Read Only Memory |
| CPU | Central Processing Unit |
| CRC | Cyclic Redundancy Check |
| DARP | Downlink Advanced Receiver Performance |
| DFE | Decision Feedback Equalizer |
| DSP | Digital Signal Processor |
| EDGE | Enhanced Data for Global Evolution |
| EEROM | Electrically Erasable Read Only Memory |
| EGPRS | Enhanced General Packet Radio System |
| FEC | Forward Error Correction |
| FIR | Finite Impulse Response |
| FPGA | Field Programmable Gate Array |
| FTP | File Transfer Protocol |
| GERAN | GSM EDGE Radio Access Network |
| GMSK | Gaussian Minimum Shift Keying |
| GPRS | General Packet Radio System |
| GSM | Global System for Mobile Communication |
| HTTP | Hyper Text Transport Protocol |
| IID | Independent and Identically Distributed |
| ISDN | Integrated Services Digital Network |
| ISI | Intersymbol Interference |
| LAN | Local Area Network |
| LLR | Log Likelihood Ratio |
| MAN | Metropolitan Area Network |
| MIMO | Multiple Input Multiple Output |
| MIPS | Millions of Instructions Per Second |
| MISO | Multiple Input Single Output |
| MLSE | Maximum Likelihood Sequence Estimation |
| MMSE | Minimum Mean Square Error |
| MRC | Maximal Ratio Combining |
| MSE | Mean Squared Error |
| NIC | Network Interface Card |
| PSK | Phase Shift Keying |
| QAM | Quadrature Amplitude Modulation |
| RAM | Random Access Memory |
| RF | Radio Frequency |
| ROM | Read Only Memory |
| SAIC | Single Antenna Interference Cancellation |
| SIM | Subscriber Identity Module |
| SISO | Single Input Single Output |
| SNR | Signal to Noise Ratio |
| TACS | Total Access Communications Systems |
| TCH | Transport Channel |
| TDMA | Time Division Multiple Access |
| TSC | Training Sequence |
| UMTS | Universal Mobile Telecommunications System |
| USB | Universal Serial Bus |
| UWB | Ultrawideband |
| VA | Viterbi Algorithm |
| WAN | Wide Area Network |
| WCDMA | Wideband Code Division Multiple Access |
| WiMAX | Worldwide Interoperability for Microwave Access |
| WLAN | Wireless Local Area Network |
| WLL | Wireless Local Loop |
| WMF | Whitening Matched Filter |

### Detailed Description of the Invention

The present invention is an apparatus for and method of Gaussian Minimum Shift Keying (GMSK) single antenna interference cancellation (SAIC) for use in a communications receiver. The invention comprises an interference mitigation module that is adapted to treat the problem of GMSK SAIC in a blind manner. The resulting receiver with the interference mitigation module incorporated therein exhibits high performance gain and low computational complexity while overcoming the problems of the prior art.

The interference mitigation mechanism of the present invention is suitable for use in many types of communication receivers, e.g., digital receivers. A receiver incorporating the interference mitigation mechanism of the present invention may be coupled to a wide range of channels and is particularly useful in improving the performance in GSM and other types of cellular communications systems, including but not limited to, Global Systems for Mobile communications (GSM), Code Division Multiple Access (CDMA, Time Division Multiple Access (TDMA), etc. Other wireless communications systems that can benefit from the present invention include paging communication devices, cordless telephones, telemetry systems, etc. These types of channels are typically characterized by fading and multipath propagation with rapidly changing channel impulse response. The interference mitigation mechanism of the present invention is operative to compensate for the co-channel interference added in the communications channel (e.g., cellular channel) which is also subject to multipath propagation and fading, receiver filter and any pre-channel estimation filtering.

To aid in illustrating the principles of the present invention, the apparatus and method are presented in the context of a GSM EDGE mobile station. It is not intended that the scope of the invention be limited to the examples presented herein. One skilled in the art can apply the principles of the present invention to numerous other types of communication systems as well (wireless and non-wireless) without departing from the scope of the invention.

### EXAMPLE COMMUNICATIONS SYSTEM

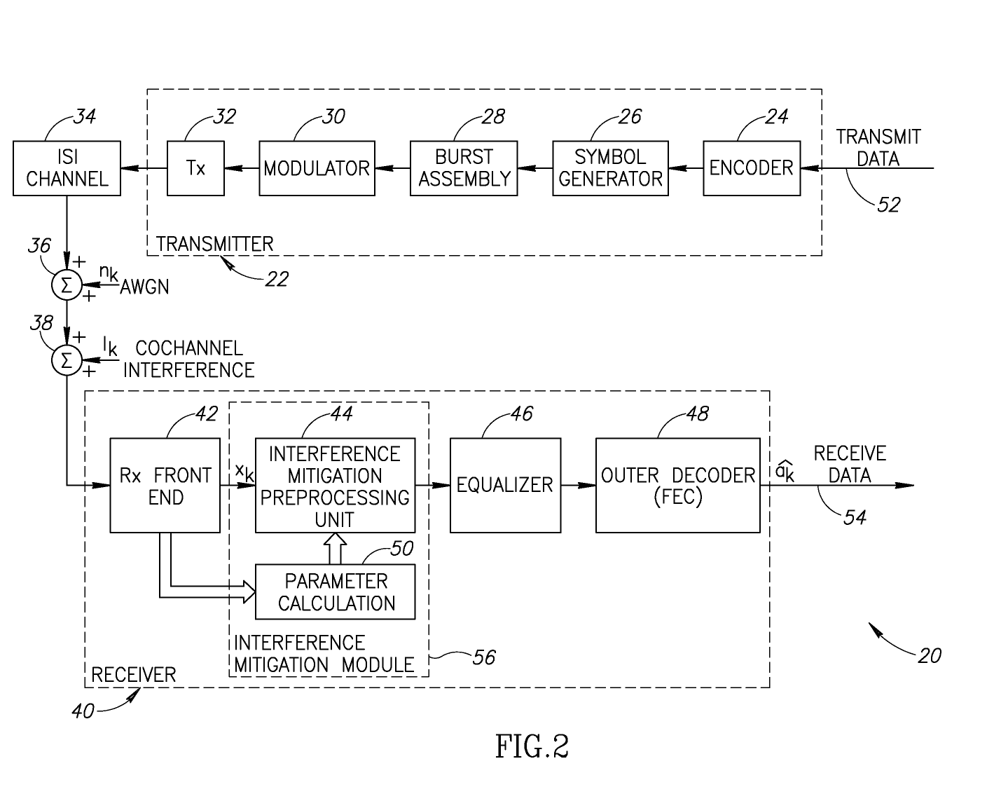

A block diagram illustrating an example communication system employing an inner and outer encoder in the transmitter, inner and outer decoding stages in the receiver and the interference mitigation mechanism of the present invention is shown in FIG. 2. The communications system, generally referenced 20, comprises a concatenated encoder transmitter 22 coupled to a time-varying, time-dispersive additive white Gaussian noise (AWGN) channel (shown as ISI channel 34 with AWGN nₖ added 36) and a concatenated decoder receiver 40. The transmitter comprises a channel encoder 24, optional interleaver (not shown), symbol generator (i.e. bit to symbol mapper) 26, burst (i.e. message) assembly 28, modulator 30 and transmit circuit 32 which comprises a transmit pulse shaping filter.

Transmit data comprising input data bits 52 to be transmitted are input to the encoder which may comprise an error correction encoder such as Reed Solomon, convolutional encoder, parity bit generator, etc. The encoder functions to add redundancy bits to enable errors in transmission to be located and fixed. The bits output of the encoder are then input to an optional interleaver which functions to rearrange the order of the bits in order to more effectively combat burst errors in the channel. The rearrangement of the bits caused by interleaving improves the resistance to burst errors while adding latency and delay to the transmission.

The bits output of the interleaver are then mapped to symbols by the symbol mapper. The bit to symbol mapper functions to transform bits to modulator symbols from an M-ary alphabet. The symbols output from the mapper are input to the modulator which functions to receive symbols in the M-ary alphabet and to generate an analog signal therefrom. The transmit circuit amplifies, filters and modulates this signal into the desired frequency band before transmitting it over the channel. Up-conversion is necessary for transmission over wireless channels. The transmit circuit comprises coupling circuitry required to optimally interface the signal to the channel medium.

In the example presented herein, the channel is a mobile radio channel that suffers from multipath propagation which causes frequency selective fading and ISI (i.e. time dispersion). Examples include paging, cellular, cordless, fixed wireless channel, e.g., satellite. The channel may also comprise a wired channel, for example xDSL, ISDN, Ethernet, etc. In all cases, it is assumed that AWGN is added to the signal in the channel. Furthermore, an interfering signal with a similar modulation scheme and similar propagation conditions (i.e. time varying multipath channel) is added 38 to the channel. This interfering signal is termed here as the co-channel interference Iₖ. The transmitter is adapted to generate a signal that can be transmitted over the channel so as to provide robust, error free detection by the receiver.

It is noted that both the inner and outer decoders in the receiver have complimentary encoders in the transmitter. The outer encoder in the transmitter comprises the encoder, e.g., convolutional, etc. The inner encoder comprises the channel itself, which can be modeled as an L-symbol long FIR-type channel.

At the receiver, the analog signal from the channel is input to RF front end circuitry 42 which demodulates and samples the received signal to generate complex I and Q received samples xₖ.

The complex samples are stored in a memory buffer, e.g., a RAM buffer, for access by the various processing blocks in the receiver, e.g., channel estimation, post sampling filter, WMF, equalizer, etc. The equivalent discrete time model for the received symbol at the k^{th} sampling instant is given by:

$$\begin{matrix}{x}_{k} = {\sum }_{i = 1}^{{L}_{h}} {h}_{i} * {a}_{k - i} + {I}_{k} + {n}_{k} & ( 1 ) \\ {I}_{k} = {\sum }_{i = 1}^{{L}_{g}} {g}_{i} * {b}_{k - i} & ( 2 )\end{matrix}$$

xₖ represents the k^{th} received sample;
aₖ₋ᵢ represents the k-i^{th} data symbol of the signal of interest;
hᵢ represents the impulse response of the desired signal channel;
Iₖ represents the co-channel interference signal;
bₖ₋ᵢ represents the k-i^{th} data symbol of the interfering signal;
gᵢ represents the impulse response of the interfering signal channel;
nₖ represents the zero mean additive white Gaussian noise (AWGN) component;
Lₕ represents the signal of interest channel impulse response length;
L_{g} represents the interfering signal channel impulse response length;

The symbols are then optionally filtered using a post sampling filter (not shown). Note that typical modem receivers comprise a rejection filter in the Rx front end commonly called the receive filter. The receive filter functions to reject out-of-band noise, e.g., thermal, etc. The effect of the transmit pulse shaping filter, ISI channel and receive filter is to color the noise. The receiver therefore employs an interference mitigation module 56 (comprising interference mitigation preprocessing unit 44 and parameter calculation module 50) that is matched to the cascade of the transmit pulse shaping filter, the ISI channel impulse response and the receive filter and jointly filters out the co-channel interference elements in terms of a spatial temporal filtering.

Note that several methods of channel estimation and channel order selection are known in the art and suitable for use with the present invention including, for example U.S. Pat. No. 6,907,092, entitled “Method Of Channel Order Selection And Channel Estimation In A Wireless Communication System,” incorporated herein by reference in its entirety.

The inner decoder (i.e. the equalizer) 46 is operative to generate decisions from the data samples. An example of an inner decoder is an equalizer which compensates for the ISI caused by the delay and time spreading of the channel. The function of the equalizer is to attempt to detect the symbols that were originally transmitted by the modulator. The equalizer is adapted to output symbol decisions and may comprise, for example the well known maximum likelihood sequence estimation (MLSE) based equalizer that utilizes the well known Viterbi Algorithm (VA), linear equalizer or decision feedback equalizer (DFE).

Most communication systems must combat a problem known as Intersymbol Interference (ISI). Ideally, a transmitted symbol should arrive at the receiver undistorted, possibly attenuated greatly and occupying only its time interval. In reality, however, this is rarely the case and the received symbols are subject to ISI. Intersymbol interference occurs when one symbol is distorted sufficiently that is occupies time intervals of other symbols.

The situation is made even worse in GSM communications systems as the GSM transmitter contributes its own ISI due to controlled and deliberate ISI from the transmitter's partial response modulator. The effects of ISI are influenced by the modulation scheme and the signaling techniques used in the radio.

Equalization is a well known technique used to combat intersymbol interference whereby the receiver attempts to compensate for the effects of the channel on the transmitted symbols. An equalizer attempts to determine the transmitted data from the received distorted symbols using an estimate of the channel that caused the distortions. In communications systems where ISI arises due to partial response modulation or a frequency selective channel, a maximum likelihood sequence estimation (MLSE) equalizer is optimal. This is the form of equalizer generally used in GSM, EDGE and GERAN systems.

The MLSE technique is a nonlinear equalization technique which is applicable when the radio channel can be modeled as a Finite Impulse Response (FIR) system. Such a FIR system requires knowledge of the channel impulse response tap values. As described supra, the channel estimate is obtained using a known training symbol sequence to estimate the channel impulse response.

There exist other equalization techniques such as Decision Feedback Equalization (DFE) or linear equalization. All these equalization techniques require precise knowledge of channel.

In GSM, the training sequence is sent in the middle of each burst. As each fixed length burst consists of 142 symbols preceded by 3 tail symbols and followed by 3 tail symbols and 8.25 guard symbols. The 142 symbols include a 58 symbol data portion, 26 symbol training sequence and another 58 symbol data portion. Since the training sequence is sent in the middle of the burst, it is referred to as a midamble. It is inserted in the middle of the burst in order to minimize the maximum distance to a data bit thus minimizing the time varying effects at the ends of the burst.

The training sequences comprise sequences of symbols generated to yield good autocorrelation properties. The receiver control algorithm uses the training sequence, received in the presence of ISI, to determine the characteristics of the channel that would have generated the symbols actually received. GSM uses eight different training sequences whereby the autocorrelation of each results in a central peak surrounded by zeros. The channel impulse response can be measured by correlating the stored training sequence with the received sequence.

The MLSE equalizer (also called a Viterbi equalizer) uses the Viterbi algorithm along with inputs and an estimate of the channel to extract the data. The equalizer generates a model of the radio transmission channel and uses this model in determining the most likely sequence. An estimate of the transfer function of the channel is required by the MLSE equalizer in order to be able to compensate for the channel ISI effect.

The MLSE equalizer operates by scanning all possible data sequences that could have been transmitted, computing the corresponding receiver input sequences, comparing them with the actual input sequences received by computing the modified metric of the present invention in accordance with the parameters and selects the sequence yielding the highest likelihood of being transmitted. Considering that ISI can be viewed as unintentional coding by the channel, the Viterbi algorithm used in the MLSE equalizer can be effective not only in decoding convolutional code sequences but in combating ISI. Typically, the MLSE equalizer comprises a matched filter (i.e. FIR filter) having L taps coupled to a Viterbi processor. The output of the equalizer is input to the Viterbi processor which finds the most likely data sequence transmitted.

The channel estimate is used by the interference mitigation module and the equalizer in processing the data blocks on either side of the training sequence midamble. A tracking module may be used to improve the performance of the receiver. If a tracking module is employed, the equalizer is operative to use the initial channel estimate in generating hard decisions for the first block of data samples. Decisions for subsequent data blocks are generated using updated channel estimates provided by the tracking module. The equalizer is also operative to generate preliminary decisions which are used by the tracking module in computing the recursive equations for the updated channel estimate.

Depending on the particular equalizer used, the output of the equalizer comprises hard symbol decisions. The hard decisions are then input to a soft value generator (not shown) which is operative to output soft decision information given (1) hard symbol decisions from the inner decoder, (2) channel model information h(k), and (3) the input samples received from the channel.

The soft decision information for a symbol is derived by determining the conditional probability of the input sample sequence given the hard symbol decision sequence. The soft decision is calculated in the form of the log likelihood ratio (LLR) of the conditional probability.

The noise variance of the channel also used by the soft value generator in generating the soft information. A soft symbol generator suitable for use with the present invention is described in more detail in U.S. Pat. No. 6,731,700, entitled “Soft Decision Output Generator,” incorporated herein by reference in its entirety.

The log likelihood ratio is defined as the ratio of the probability of a first symbol with a second symbol wherein the second symbol is a reference symbol. The reference symbol is arbitrary as long as it is used consistently for all the soft output values for a particular time k. The reference symbol can, however, vary from time k+1, k+2, etc. Preferably, however, the reference is kept the same throughout.

Note that a hard decision is one of the possible values a symbol can take. In the ideal case, a soft decision comprises the reliabilities of each possible symbol value. The soft decision comprises a complete information packet that is needed by the decoder. An information packet is defined as the output generated by a detector or decoder in a single operation.

The soft decision information output of the equalizer (or soft value generator) is input to the outer decoder 48 which is preferably an optimal soft decoder. The outer decoder functions to detect and fix errors using the redundancy bits inserted by the encoder and to generate the binary receive data. Examples of the outer decoder include convolutional decoders utilizing the Viterbi Algorithm, convolutional Forward Error Correction (FEC) decoders, turbo decoders, etc. Soft input Viterbi decoders have the advantage of efficiently processing soft decision information and providing optimum performance in the sense of minimum sequence error probability.

Note that optionally, a de-interleaver (not shown) may be used in the receiver (and correspondingly in the transmitter). In this case, a symbol based interleaver/de-interleaver is used to reconstruct the original order of the data input to the transmitter. If a bit based interleaver/de-interleaver is used, a mechanism of mapping soft symbols to bits must be used before the outer decoder, such as described in U.S. Pat. No. 6,944,242, entitled “Apparatus For And Method Of Converting Soft Symbol Information To Soft Bit Information,” incorporated herein by reference in its entirety.

### GMSK Receiver Demodulator

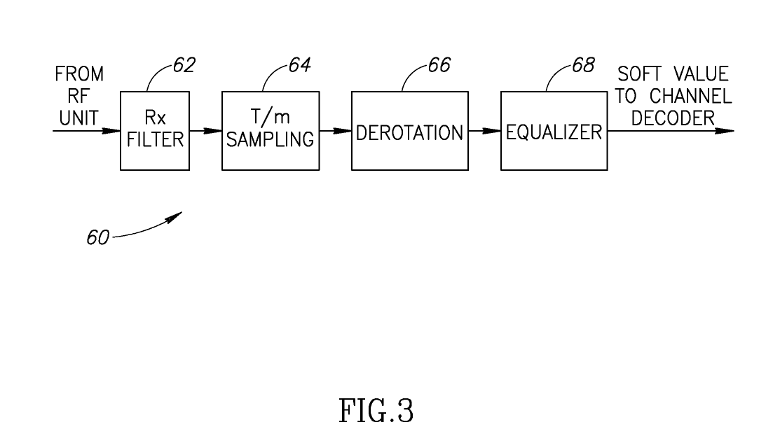

A block diagram illustrating the signal flow of a typical GSM receiver demodulator is shown in FIG. 3. A received GMSK signal may be considered as a rotated BPSK signal with signaling of ±1 at each time interval T. The BPSK signal is rotated counterclockwise in the IQ plane by π/2 radians every signaling time interval T. The operation of a preferred GMSK receiver demodulator, generally referenced 60, is as follows. First, the signal received from the RF front end circuit is filtered by the Rx filter 62, then sampled (block 64) with a T/m sampling period (i.e. sampling at m points within each signaling interval). De-rotation is then applied (block 66) in order to cancel the rotation implemented at the transmitter, resulting in a BPSK modulated signal which is subject to inter-symbol interference (ISI). Eventually, the reconstructed BPSK signal feeds an equalizer 68, designated to cancel the ISI and simultaneously decode the original BPSK signal.

A motivation for the proposed interference mitigation mechanism is that the GMSK signal modulates ±1 symbols from a real constellation. Hence, the signal resides along a single axis in the complex plane. The received signal, however, comprises multiple branches conveying this signal. These branches can be (1) the in-phase and quadrature elements of the signal, (2) the sampling phases if over-sampling (i.e. T/m sampling) is applied and (3) signals from multiple antennas. Thus, it is advantageous to take into account the spatial diversity provided by these multiple representations of the signal and to collapse or combine the information in the branches into a one (or two) branches that feed the equalizer.

It is important to note that the interference mitigation mechanism of the present invention is not limited to real constellations as in the case of BPSK and offset BPSK, or to non-linear modulation, e.g., GMSK, that can be approximated as linear modulations mentioned above. Complex constellations also benefit from applying the interference mitigation mechanism of the present invention to multiple representation of the received signal. In this case, over-sampling and multiple antennas provide the multiplicity of representation and in-phase and quadrature signals comprise a single complex branch.

### Interference Mitigation Module and GMSK Equalizer Architecture

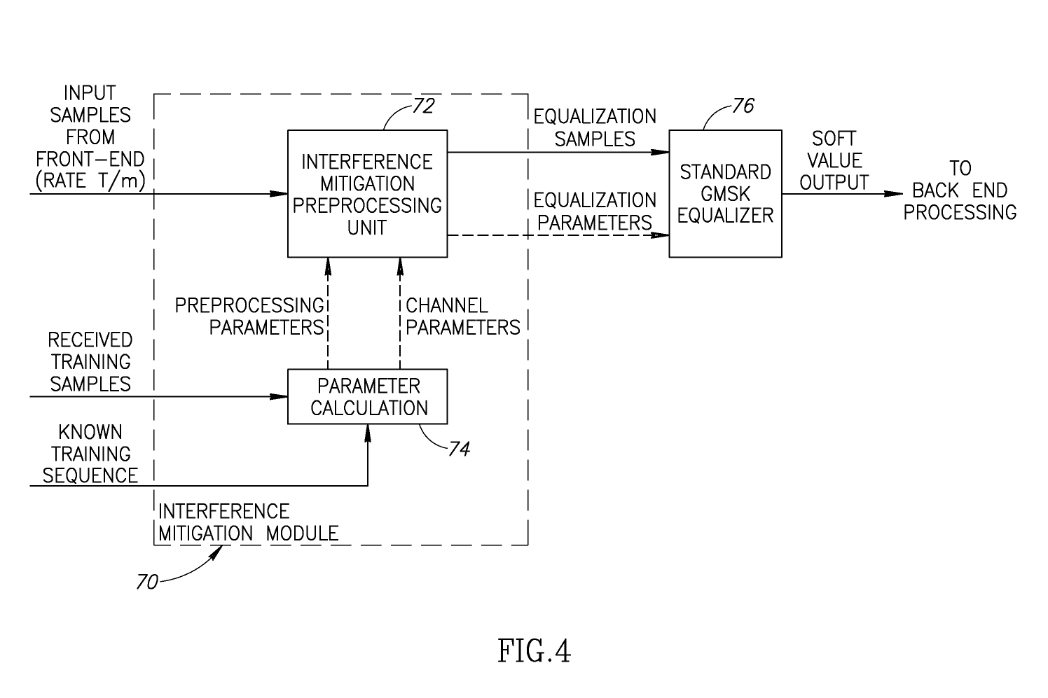

A block diagram illustrating the interference mitigation module and equalizer of the present invention with blind SAIC is shown in FIG. 4. The interference mitigation module (or SAIC module) 70, coupled to a conventional GMSK equalizer 76, comprises an interference mitigation preprocessing unit 72 and parameter calculation unit 74. In accordance with the invention, the SAIC module is adapted to be an add-on unit applied to the input of a conventional GMSK equalizer. In addition, both the equalizer and the pre-processing unit are supported by a parameter calculation unit which functions to provide the corresponding necessary parameters. These parameters are calculated according to training data, as described in more detail infra.

The parameter calculation unit is adapted to provide the preprocessing and channel parameters to the preprocessing unit as a function of the received training samples and the known training response. The preprocessing unit applies the input samples from the Rx front end to a MIMO filter (described in more detail infra) and generates equalization samples and parameters subsequently passed to the equalizer 76.

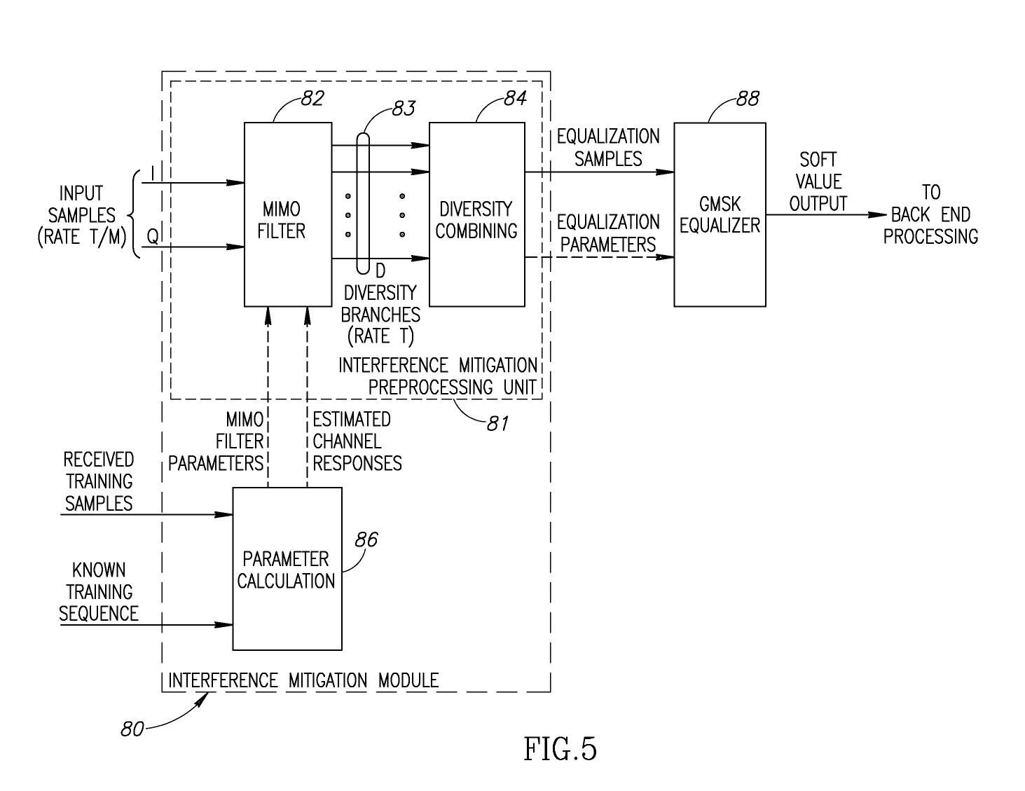

A block diagram illustrating an example SAIC interference mitigation module and equalizer of the present invention is shown in FIG. 5. The interference mitigation module 80, coupled to GMSK equalizer 88, comprises an interference mitigation preprocessing unit 81 and parameter calculation unit 86. The interference mitigation preprocessing unit comprises a Multiple Input Multiple Output (MIMO) filter 82 and diversity combiner 84.

The parameter calculation unit functions to generate the MIMO filter parameters and estimated channel responses based on the received training samples and the known training response. The MIMO filter 82 generates D output diversity branches 83 as a functions to the IQ input samples (or other spatial diverse input), MIMO filter parameters and estimated channel responses. The diversity combiner 84 collapses the D output diversity branches to a single branch represented by the equalization samples and equalizer parameters that are input to the equalizer 88.

In operation, the MIMO filter takes as input the IQ elements, over-sampling phases and the inputs of multiple antennas (i.e. spatially diverse input). A key feature of the MIMO filter is that a number D of output diversity branches 83 may be larger than the dimension of the input constellation. As shown in more detail infra, this feature significantly improves the performance of the receiver.

The invention also comprises an optimization criterion for determining the MIMO filter coefficients. A benefit of the optimization criterion is that it increases the sum of the SNRs measured over the MIMO filter output branches. In addition, the channel taps are estimated jointly with the MIMO filter coefficients. Further, the outputs of the MIMO filter are input to a diversity combining unit 84 which generates a single branch output with no loss of relevant information. Consequently, the preprocessing unit 80 can be used with conventional (i.e. non-spatial) equalizers such as the Ungerboeck equalizer.

### The MIMO Filter

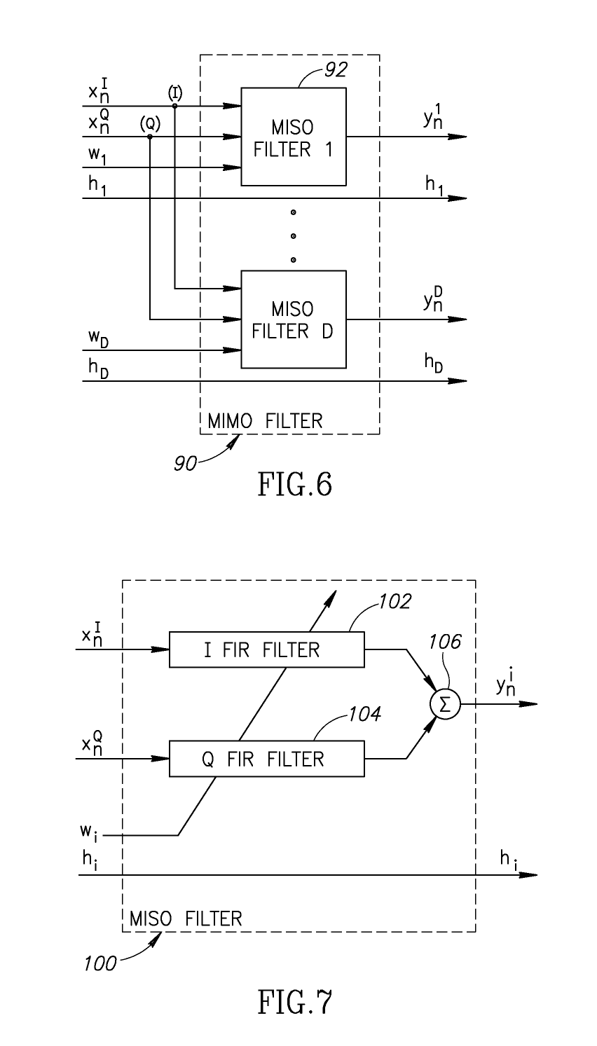

A block diagram illustrating the MIMO filter of the present invention is shown in FIG. 6. The MIMO filter, generally referenced 90, is the key element of the pre-equalizer interference mitigation module. The structure and operation of the MIMO filter is described in the context of a single antenna and no over-sampling. The extension of the mechanism to multiple antennas and over-sampling is straightforward and is described infra.

Described hereinbelow is the architecture of the MIMO filter, the method of calculating the parameters, an extension of the MIMO filter to the case of multiple antennas and/or over-sampling and an additional extension of the MIMO filter to the case of complex constellations.

With reference to FIG. 6, the architecture of the MIMO filter will now be described in more detail The input to the MIMO filter comprises (1) the I and Q components of the equalizer's input sequence and (2) a set of parameters. The outputs of the MIMO filter comprises D distinct branches with multiplicity as the diversity order. The MIMO filter comprises a plurality of D disjoint Multiple Input Single Output (MISO) filters 92. Each of the MISO filters receive as input the same input samples (xₙ^{I}, xₙ^{Q}). The following description of the operation of the MIMO filter uses the following notation:
xₙ^{I} the in-phase (I) component of the equalizer's input sample at time instance n;
xₙ^{Q} the quadrature (Q) component of the equalizer's input sample at time instance n;
yₙⁱ the output sample of the i^{th} MISO filter at time instance n;
wᵢ the parameter vector of i^{th} MISO filter;
hᵢ the channel impulse response corresponding to the i^{th} branch;
D the number of diversity branches (and MISO filters);

Each MISO filter has associated with it, its own set of filter taps and corresponding channel impulse response. Each individual MISO filter is provided a distinct parameter vector wᵢ which results in the generation of a correspondingly distinct sequence yₙⁱ with each sequence orthogonal to the others. The solid line adjacent to each MISO filter represents a corresponding channel impulse response hᵢ. Although the channel impulse response does not affect the functionality of the MISO filter, it is used in the diversity combiner that follows the MISO filter.

A block diagram illustrating the MISO filter of the present invention is shown in FIG. 7. The MISO filter, generally referenced 100, comprises an I FIR filter 102, Q FIR filter 104 and adder 106. It is important to note that the MISO filter is a real system, i.e. all inputs, outputs and parameters (xₙ^{I}, xₙ^{Q}, yₙⁱ) are real numbers. Furthermore, it is important to note that all operations within the MISO filter are real as well.

The operation of the MISO filter is described as follows. Both xₙ^{I} and xₙ^{Q} are filtered by two disjoint real finite impulse responses (FIR) filters 102, 104. Once filtered, the outputs of the filters are summed and resulting in an output sequence yₙⁱ. The channel impulse response hᵢ corresponds to the current branch.

The relationship between the inputs and output of the MISO filter is described mathematically as follows:
Yₙⁱ=xₙ^{I}*wₙ^{I,i}+xₙ^{Q}*wₙ^{Q,i} (3)
where
‘*’ denotes a linear convolution operator;

wₙ^{I,i} and wₙ^{Q,i} for n=0,1, . . . p−1 represent the coefficients of the I (in-phase) and Q (quadrature) components of wᵢ, respectively;

In other words, the parameter vector wᵢ presented above comprises the coefficients wₙ^{I,i} and wₙ^{Q,i}. Note that p may be considered as the temporal whitening order in the preprocessing unit.

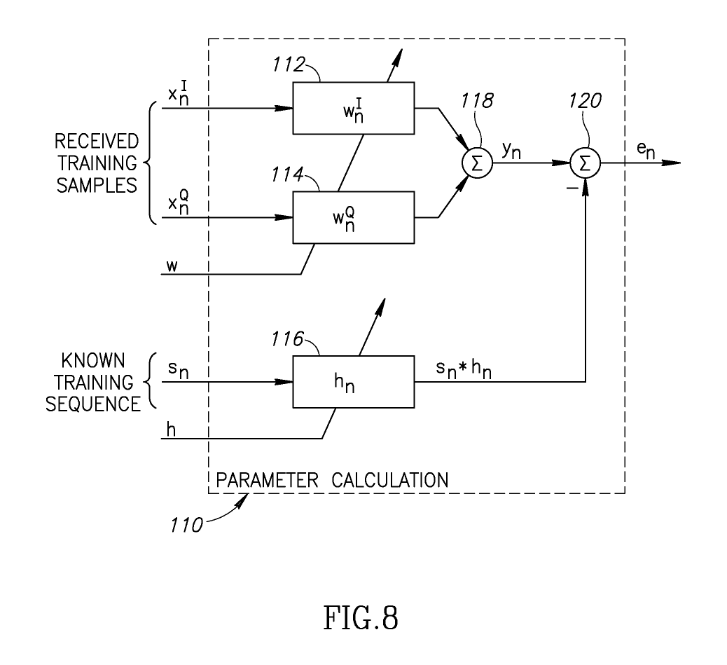

Several definitions of the measures used in the parameter calculation process are provided below. A common practice in GSM receivers is to calculate parameters over the samples of a training sequence comprising the mid-amble of a burst. A block diagram illustrating the parameter calculation metric of the present invention for a single branch is shown in FIG. 8. Note that this figure and its related discussion refer to the parameter calculation process of the i^{th} branch. For clarity sake, however, the symbol i is omitted from the notation.

The parameters calculation unit 110 comprises convolution blocks 112, 114, 116 and adders 118, 120. The following equation represents the calculation performed by the unit 110.

$$\begin{matrix}{e}_{n} = {y}_{n} - {s}_{n} * {h}_{n} \\ = {x}_{n}^{I} * {w}_{n}^{I} + {x}_{n}^{Q} * {w}_{n}^{Q} - {s}_{n} * {h}_{n}\end{matrix} \qquad ( 4 )$$

where
eₙ denotes the training error;
sₙ denotes the (known) training sequence;
xₙ^{I}, xₙ^{Q} are the received training sequence samples excited by the training sequence sₙ at the transmitter;

Applying further manipulations, Equation 4 can be written in either of two ways. The first uses a vector notation as follows:
eₙ=xₙ^{T}w−sₙ^{T}h (5)

The second uses a matrix notation as follows:
e=Xw−Sh (6)

The elements used in the above equations are defined as follows:
h The vector of the channel impulse response corresponds to a specific MISO filter (branch). h :=[h₀, . . . , h_{L-1}]^{T}, where L is the assumed channel length and [.]^{T} denotes a ‘vector transposition’ operator.
w The column vector representing the MISO FIR coefficients and comprising the coefficients of the I and Q FIR filter side by side: w :=[w₀^{I}, . . . , wₚ₋₁^{I}, w₀^{Q}, . . . , Wₚ₋₁^{Q}]^{T}.
xₙ The column vector containing the training sequence samples.

$${x}_{n} \text{:} = {[ {x}_{n}^{I} , … , {x}_{n - ( p - 1 )}^{I} , {x}_{n}^{Q} , … , {x}_{n - ( p - 1 )}^{Q} ]}^{T}$$
sₙ The column vector containing the training sequence. sₙ :=[sₙ, . . . , s_{n-(L-1)}]^{T}
X The matrix containing the training samples, whereby:

$$X \text{:} = [ \begin{matrix}{x}_{L - 1}^{I} & {x}_{L - 2}^{I} & ⋯ & {x}_{L - ( p - 1 )}^{I} & {x}_{L - 1}^{Q} & {x}_{L - 2}^{Q} & ⋯ & {x}_{L - ( p - 1 )}^{Q} \\ {x}_{L}^{I} & {x}_{L - 1}^{I} & ⋯ & {x}_{L + 1 - ( p - 1 )}^{I} & {x}_{L}^{Q} & {x}_{L - 1}^{Q} & ⋯ & {x}_{L + 1 - ( p - 1 )}^{Q} \\ ⋮ & & & & & & & ⋮ \\ {x}_{N - 1}^{I} & {x}_{N - 2}^{I} & ⋯ & {x}_{N - 1 - ( p - 1 )}^{I} & {x}_{N - 1}^{Q} & {x}_{N - 2}^{Q} & ⋯ & {x}_{N - 1 - ( p - 1 )}^{Q}\end{matrix} ] .$$

It can be seen that X actually builds two Toeplitz matrices, for the I and Q parts of the training samples, respectively, placed side by side.
S The Toeplitz matrix containing the training sequence:

$$S \text{:} = [ \begin{matrix}{s}_{L - 1} & {s}_{L - 2} & ⋯ & {s}_{0} \\ {s}_{L} & {s}_{L - 1} & ⋯ & {s}_{1} \\ ⋮ & & & ⋮ \\ {s}_{N - 1} & {s}_{N - 2} & ⋯ & {s}_{N - 1 - ( L - 1 )}\end{matrix} ] .$$
e The training error vector. e :=[e_{L-1}, . . . , e_{N-1}]^{T}, where N is the length of the training sequence.
L The length of the channel impulse responses h.
p The length (in the time domain) of the MISO filters.

In the case of multiple diversity branches, every branch i comprises its own parameters, channel impulse response, output signals, etc. as distinguished by the subscript or superscript i, accordingly. Note that S and X are given matrices, S being a constant matrix and X being a matrix of input samples. The vectors w and h are tunable parameter vectors which are derived according to some predetermined quality measure.

### The Parameter Calculation Optimization Problem and its Solution

We consider the following matrix definitions Rₛₛ, Rₓₓ and Rₛₓ for the transmitted signal: Rₛₛ is the auto-correlation matrix; Rₓₓ is the received signal auto-correlation matrix and Rₛₓ is the transmitted signal with received signal cross-correlation matrix.

It is noted that the above mentioned three matrices Rₛₛ, Rₓₓ and Rₛₓ may be calculated using either: (1) a statistical approach (e.g., Rₛₛ :=E(sₙsₙ^{T}), where E(•) denotes the expectation operator) or (2) using a deterministic approach (e.g., Rₛₛ :=S^{T}S).

Note also that a special characteristic exists for the second order statistic analysis in the problem with regards to the above mentioned matrices. It is observed that both approaches result in similar expressions. This characteristic is preserved for all the power quantities involved in the derivation. For example, the signal power in a statistical approach is expressed as follows:
E(sₙ*hₙ)²=E(sₙ^{T}h)²=h^{T}Rₛₛh (7)
Taking the deterministic approach on the other hand, the signal power becomes:
||Sh↑↑²=h^{T}S^{T}Sh=h^{T}Rₛₛh (8)
Let us now introduce the following intermediate matrix:
P:=Rₛₛ⁻¹[Rₛₛ−RₛₓRₓₓ⁻¹Rₓₛ] (9)
where P is an L×L matrix.

A useful approximation for P may be introduced using the following approximation: Rₛₛ≈kI, where k is a constant scalar and I is the identity matrix of the appropriate dimension. This approximation stems from the fact that training sequences in many cases are pseudo random and pseudo white in nature. Taking this into account we can take P to be:
{tilde under (P)}=Rₛₛ−RₛₓRₓₓ⁻¹Rₓₛ (10)
For all i=1, . . . , D, the filter is expressed by the following:
hᵢ=vᵢ/\sqrt{λᵢ}wᵢ=Rₓₓ⁻¹Rₓₛhᵢ (11)
where vᵢ is an eigenvector of P corresponding to the eigenvalue λᵢ, wherein the eigenvectors are orthogonal to each other. In some cases it is beneficial to sort the eigenvalues in an ascending order λ₁≦ . . . ≦λ_{L}. It stems from this solution that D, which denotes the number of branches selected, is upper bounded by L: D≦rank(P)≦L. It is important to note that D may be larger than the dimension of the input signal. For example, consider a T sampled GMSK received signal with single antenna. In this case, the received signal is complex and therefore has a dimension of two while D may be five. Thus, without the need for an iterative approach, the mechanism of the present invention benefits from the use of all the spatial diverse branches of the input received signal.

The above mentioned solution is a result of an optimization criterion that might be termed “maximizing the sum of SNRs in D diversity branches” (max sum SNR). This optimization criterion is an extension of a different approach to maximize the SNR. We define the SNR as follows:

$$SNR = \frac{{h}^{T} {R}_{ss} h}{{w}^{T} {R}_{xx} w + {h}^{T} {R}_{ss} h - 2 {w}^{T} {R}_{xs} h} \qquad ( 12 )$$

The max sum SNR optimization problem can be expressed in more detail as:

$$max {\sum }_{i = 1}^{D} {SNR}_{i} \\ \begin{matrix}s . t . ∀ i \neq j E ( {e}_{n}^{i} {e}_{n}^{j} ) = 0 or {e}_{i}^{T} {e}_{j} \\ = 0 \\ ∀ i {E ( {e}_{n}^{i} )}^{2} = 1 or {e}_{i}^{T} {e}_{i} \\ = 1\end{matrix} \qquad ( 13 )$$

In (13) we solve for: h₁, . . . , h_{D}, w₁, . . . , w_{D}.

It is observed that having D distinct solutions (with orthogonal errors) and appropriately combining them results in a monotonic increase in D of performance. This substantially differs from maximizing the SNR term defined in Equation 12 which corresponds to taking a single branch defined by a single pair of w and h which correspond to the best eigenvalue.

It appears that the solution for another well known optimization criterion: the minimal mean squared error solution, results in a similar form when allowing an increase of the solution dimension (i.e. using D diversity branches). Using a power constraint with the approximation: Rₛₛ≈kI, results in a similar solution as the max sum SNR criterion presented above. The optimization problem can be approached also by taking a joint power constraint which shows better performance in the expanse of increased complexity. One may consider also a monic constraint for the problem.

### Extension to Multiple Antennas and Over-sampling

Extending the MIMO filter to multiple antennas and over-sampling is straightforward to one skilled in the art. The additional samples provided by multiple antennas and additional sampling phases are treated as extra data branches. These branches are then fed in parallel to a MIMO filter in a similar manner to that presented supra.

Let K be the number of antennas and M the over-sampling factor. In this case, each of the MISO filters takes 2×K×M input branches instead of two input branches (i.e. such as the case of T spaced sampling and single antenna). Accordingly, the MISO filter has a distinct FIR filter for every input branch and the outputs of all FIR filters are summed at the output of the MISO filter.

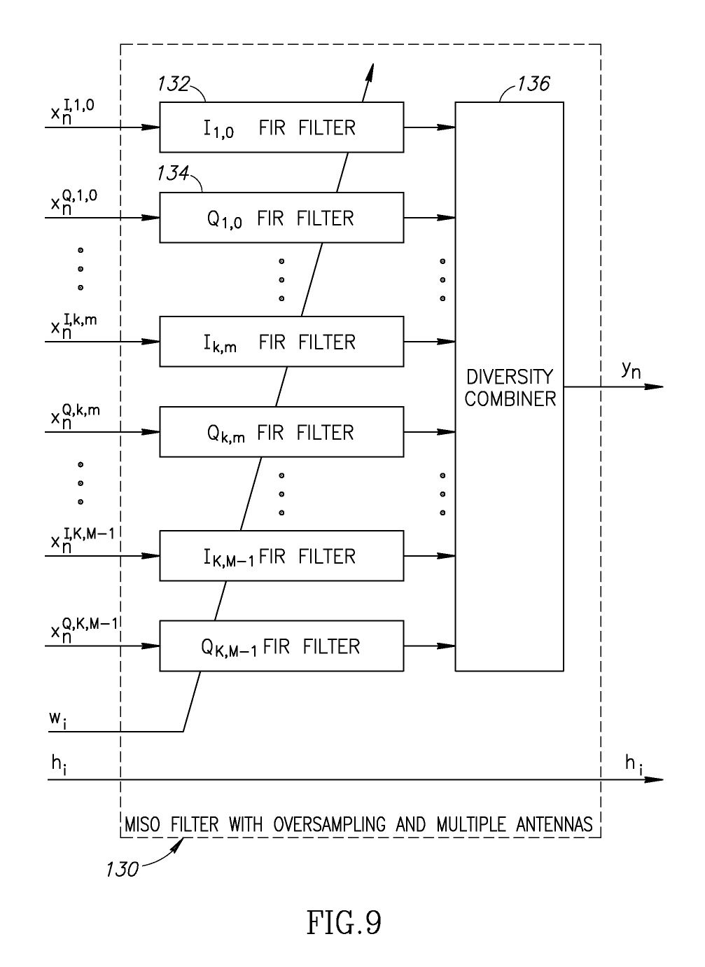

A block diagram illustrating the MISO filter with over sampling and multiple antennas constructed in accordance with the present invention is shown in FIG. 9. The MISO filter, generally referenced 130, comprises a plurality K×M pairs of I and Q FIR filters 132, 134, respectively, and diversity combiner 136.

Let T denote the symbol period. In the case where T spaced sampling is performed the continuous time input x(t) is sampled each T time interval as follows:
xₙ=x(t₀+nT) (14)
where t₀ is a constant sampling time phase. Implementing sampling at T/M period (i.e. M samples per symbol), we define

$$\begin{matrix}{x}_{n , m} = x ( {t}_{0} + \frac{T}{M} ( Mn + m ) ) \\ = x ( {t}_{0} + T ( n + \frac{m}{M} ) )\end{matrix} \qquad ( 15 )$$

Observe that now, each sample, xₙ (originally created in a T spaced sampling system) is replaced by M consecutive samples x_{n,0}, x_{n,2}, . . . , x_{n,M-1}. In other words, each sampling point has M, equally spaced, sampling phases.

Extending the approach to the notation presented above, the MIMO inputs are defined as the set xₙ^{I,k,m}, xₙ^{Q,k,m} with m∈{0, . . . , M−1}being the sampling phase and k∈{1, . . . , K} being the antenna index. Each MISO filter is now fed with all these branches in parallel.

Note that the associated parameter calculation is performed in the same way as in the case of a single antenna with no over-sampling. The only difference being that the wᵢ vectors (comprising the MISO filter parameters) and the xₙ vector or X matrix (comprising the MISO filter inputs) are expanded appropriately. wᵢ is expanded by simply concatenating the parameters corresponding to each input branch FIR while xₙ (or X) is expanded by concatenating the new input vectors (or matrices) of the new input branches. The remainder of the parameter calculations are performed exactly as described supra.

### Extension to Signals from Complex Constellations

The framework presented above is based on the assumption that the original signal comprises a real constellation. This assumption affects the design of the MIMO filter in several aspects: (1) the received complex signal is decomposed into two real branches (i.e. I and Q), (2) all the filters comprising the MIMO system are real (all w, h), and (3) the proposed system output is a real signal.

The detailed mechanism presented supra can be extended to complex constellations (e.g., QAM, 8PSK, etc) with over-sampling applied and reception using multiple antennas. The extension is straightforward to one skilled in the art and requires the following adaptation.
1. The received signal is not decomposed into I and Q.
2. Two separate filters for I and Q in the MISO filters are not used, rather only a single complex filter is used. In the case where no over-sampling and multiple antennas are used, the MISO filters fall back to D distinct Single Input Single Output (SISO) filters. When over-sampling and multiple antennas are in use, the MISO filters remain MISO, with half of the number of filters needed in comparison to the case of a real constellation.
3. All the filters (w, h ) are now complex.
4. The system output is complex.
5. The correlation functions are extended to complex signals. i.e. r_{xy}(l)=E(xₙ₊ₗyₙ*) where (•)* denotes the conjugate-transpose operator. The appropriate addition of the conjugate-transpose operator should also be incorporated into the calculations of the auto-correlation and cross-correlation matrices (Rₓₓ, Rₓₛ, Rₛₛ).

### The Diversity Combining Unit

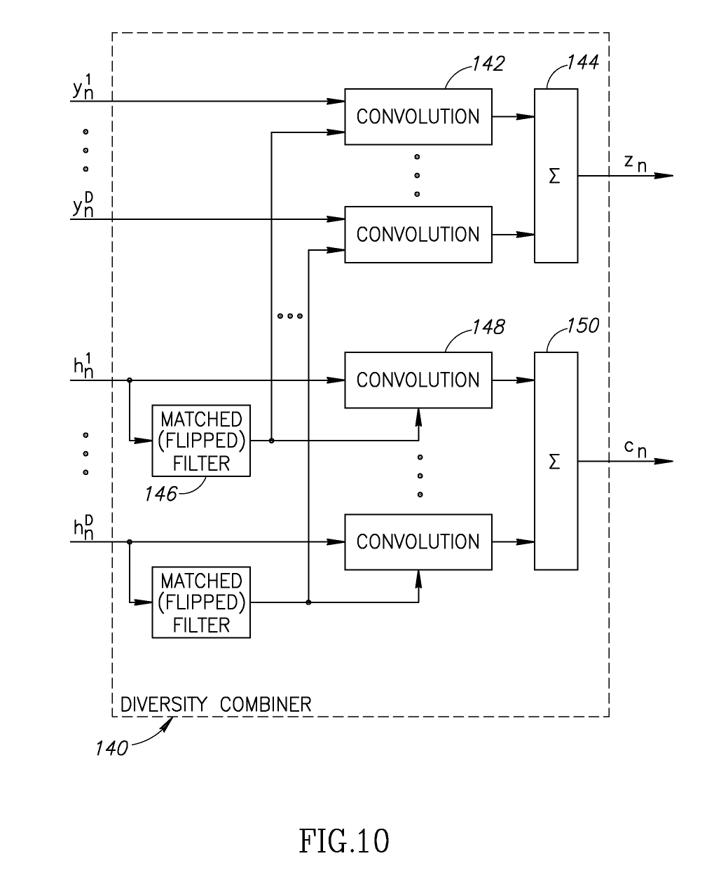

The second major component of the interference mitigation mechanism of the present invention is the diversity combining unit. A block diagram illustrating the diversity combiner of the present invention in more detail is shown in FIG. 10. The diversity combiner 140 comprises convolution blocks 142, 148, matched (flipped) filters 146 and adders 144, 150. The diversity combining functions as the interface between the MIMO filter and the equalizer. The MIMO filter provides as output D diversity branches and the diversity combining unit functions to reduce the number of branches to one. This single branch then feeds the GMSK equalizer.

The diversity combining unit comprises a matched (flipped) filter for each of D diversity branches. Every diversity branch input yₙⁱ is convolved via convolution blocks 142 with the output of its corresponding matched filter 146. The convolution outputs are then summed via adder 144. In addition, each channel response is convolved via convolution blocks 148 with its corresponding matched filter 146 resulting in a set of distinct channel auto-correlation functions. The channel auto-correlation functions are summed via adder 150. Subsequently, the sum of the convolved outputs and the sum of the channels response auto-correlations are input to an Ungerboeck equalizer. Thus, the diversity combiner is operative to factor the D diversity branches with corresponding D channel impulse responses into a single channel impulse response and single output branch.

Note that the diversity combining unit shown in FIG. 10 is adapted to be used with a particular GSMK equalizer known as an Ungerboeck MLSE equalizer. It is appreciated by one skilled in the art that the invention is not limited to use of a particular equalizer. For example, the mechanism can be used with a conventional Forney MLSE type equalizer as well. In this case, several alternatives exist. In one alternative, the diversity combining unit is not required and is therefore not used. Thus, the D diversity branches output of the MIMO filter directly feed the Forney equalizer. In this case, however, the equalizer's metric calculation must be extended to a D dimensional space accordingly. Other alternatives which permit the use of the Forney equalizer settings make use of the diversity combining unit as described supra.

Consider the problem of MLSE at the output of the MIMO filter. The output of the MIMO filter can be represented as a multi-dimensional ISI channel as follows:

$${\overline{y}}_{n} = {\sum }_{i = 0}^{L - 1} {x}_{n - i} {\overline{h}}_{i} + {\overline{v}}_{n} \qquad ( 16 )$$

The following three notations are used:
y̅ₙ:=[yₙ¹, . . . , yₙ^{D}]^{T} represents the vector output of the MIMO filter;
h̅ₙ:=[hₙ¹, . . . , hₙ^{D}]^{T} represents the vector tap of the MIMO filter at time instance n;
v̅ₙ=[vₙ¹, . . . , vₙ^{D}]^{T} represents the vector of residual error on branches 1, . . . , D;
   We note that by construction the correlation matrix of the random vector v̅ₙ is E( v̅ₙ v̅ₙ^{T})=I. Under a Gaussian assumption it is independently and identically distributed (or spatially white).

Rewriting the squared metric under the whiteness assumption results in the Euclidian distance ∥y−Hx∥² which becomes:

$${\sum }_{d = 1}^{D} {‖ {y}_{d} - {H}_{d} x ‖}^{2} \qquad ( 17 )$$

where the subscript d indicates a corresponding diversity branch d.

The extended Euclidian distance presented above, may be formed as follows:

$${\sum }_{d = 1}^{D} {‖ {y}_{d} - {H}_{d} x ‖}^{2} = {\sum }_{d = 1}^{D} {y}_{d}^{T} {y}_{d} - 2 [ {\sum }_{d = 1}^{D} {y}_{d}^{T} {H}_{d} ] x + {x}^{T} [ {\sum }_{d = 1}^{D} {H}_{d}^{T} {H}_{d} ] x \qquad ( 18 )$$

Let us define the following elements:

$$z \text{:} = {\sum }_{d = 1}^{D} {H}_{d}^{T} y$$

$${R}_{hh} \text{:} = {\sum }_{d = 1}^{D} {H}_{d}^{T} {H}_{d}$$

$$c \text{:} = {\sum }_{d = 1}^{D} conv ( {h}_{d} , flip ( {h}_{d} ) ) ,$$

which is the correlation vector forming the matrix Rₕₕ

The first element z presented above can be interpreted as an output of a multi dimensional matched filter (of D dimensions).

### Ungerboeck Equalizer

It is noted that using the notations above while omitting the constant factor Σ_{d=1}^{D}y_{d}^{T}y_{d} yields the Ungerboeck equalizer form of inputs. Therefore the pre-processing unit matches an Ungerboeck equalizer with no modifications required to the pre-processing unit algorithm. Note that in comparison to a conventional equalizer, two additional operations are needed prior to equalization. The first is to sum the matched filter outputs and the second is to sum the post flipped filter responses. These operations are performed by the diversity combining unit shown in FIG. 10.

Several benefits of the mechanism which particularly suite the Ungerboeck equalizer include:
1. Each diversity branch passes through its corresponding flipped filter which is actually its matched filter. This operation cancels the all pass elements in the corresponding channel impulse response. Therefore, a transformation to minimum phase is not needed.
2. Since the diversity combining unit converges D diversity branches into a single branch, without affecting equalizer operation, a conventional single branch, real, Ungerboeck equalizer can be used.

In an efficient implementation suitable for use with an Ungerboeck equalizer following the pre-processing unit, the MIMO filter is combined with the diversity combining unit. This integration of the MIMO filter and the diversity combining unit results in a single MISO filter which is a linear combination of the D MISO filters, each convolved with its corresponding channel impulse response. This MISO filter comprises two inputs (in the baseline case of two diversity inputs I and Q) and a single output. Each input (i.e. I and Q) is filtered with an FIR having L+p−1 coefficients. This results in increased implementation efficiency by a factor of D without any loss of gain. In addition, the channel impulse response auto-correlation function reported to the Ungerboeck equalizer can be combined as well, in accordance with this implementation.

### Forney Equalizer

Using a Forney equalizer requires additional adjustments to the diversity combining unit as presented herein. In order to match a conventional Forney equalizer, the diversity combining unit is adapted to generate two branches rather than a single branch as proposed for the Ungerboeck equalizer described supra.

A first alternative is to fold the D dimensional signal input to the diversity combining unit into two branches. Methods that can be applied to implement this approach include, for example: (1) taking only the two branches corresponding to the best eigenvalues (i.e. smallest eigenvalues) or (2) combining groups of D/2 branches using two separate diversity combining units.

A second alternative is based on using a diversity combining unit of FIG. 10. As described supra, this diversity combining unit particularly suits an Ungerboeck equalizer and results in a single output branch. This single output branch can be adapted to a Forney equalizer setup by transforming the channel impulse response into its minimum phase version using a whitening matched filter, such as described in U.S. Pat. No. 6,862,326, entitled “Whitening Matched Filter For Use In A Communications Receiver,” incorporated herein by reference in its entirety.

It is noted that the first alternative presented above is suboptimal while the second approach is optimal in the sense it does not cause any loss in relevant information. In terms of complexity, however, the first alternative is relatively simple to implement with respect to the second alternative.

The adaptation to the Forney equalizer may be approached directly, i.e. without the use of a diversity combining unit. In this alternative embodiment, the well known squared metric is extended over the complex plane to the D dimensional space. Accordingly, the multiple branch case produces the following metric:

$${\sum }_{d = 1}^{D} {‖ {y}_{d} - {H}_{d} x ‖}^{2} = {\sum }_{n = 0}^{N - 1} {\sum }_{d = 1}^{D} {( {y}_{n}^{d} - {\sum }_{i = 0}^{L - 1} {x}_{n - i} {h}_{i}^{d} )}^{2} \qquad ( 19 )$$

Using the above metric, the Forney equalizer can be implemented as in the single branch case above using the Viterbi algorithm. The only difference being the extended branch metric:

$${\sum }_{d = 1}^{D} {( {y}_{n}^{d} - {\sum }_{i = 0}^{L - 1} {x}_{n - i} {h}_{i}^{d} )}^{2} \qquad ( 20 )$$

Thus, when the Forney MLSE equalizer is used in conjunction with the metric in Equation 18, the diversity combining unit is not needed and only the metric calculation is extended. This alternative approach which does not require the diversity combining operation requires a modified Forney equalizer which is referred to as a multi-dimension metric Forney equalizer.

### Simulation Results

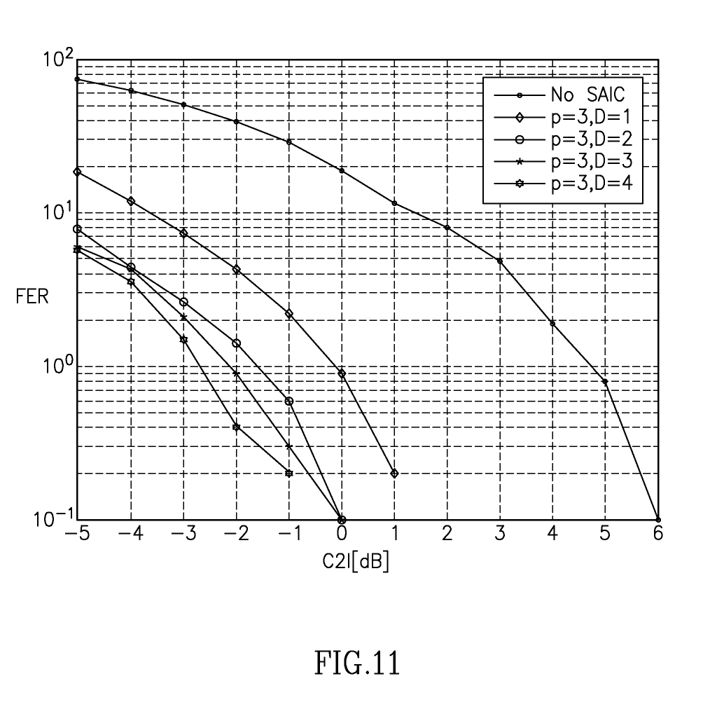

A graph illustrating simulation results for a receiver implementing the interference mitigation mechanism of the present invention with respect to a conventional receiver is shown in FIG. 11. The frame error rate (FER) results are presented for a practical study case known as TCH/AFS5.9 under DTS1. Note that TCH/AFS5.9 comprises a sample of an Adaptive Multi Rate (AMR) Transport Channel (TCH) while DTS or DARP Testing Scheme is a testing scenarios defined in the GSM standard.

With reference to FIG. 11, the dotted curve represents the reference results of a conventional receiver. The other four curves presented show performance for a value of the temporal whitening order in the preprocessing unit p=3 with respect to varying diversity orders from D=1 though 4, with D=1 represented by the diamond curve, D=2 represented by the circle curve, D=3 represented by the ‘X’ curve and D=4 represented by the star curve. It is important to note that the curves presented show a monotonically increasing improvement with respect to the diversity order. Increasing the diversity order to four results in an additional algorithmic gain of 1 dB with respect to the case where the diversity order D=2. Note that the overall gain observed for p=3 and D=4 approaches 7.5 dB.

### GSM EDGE Embodiment

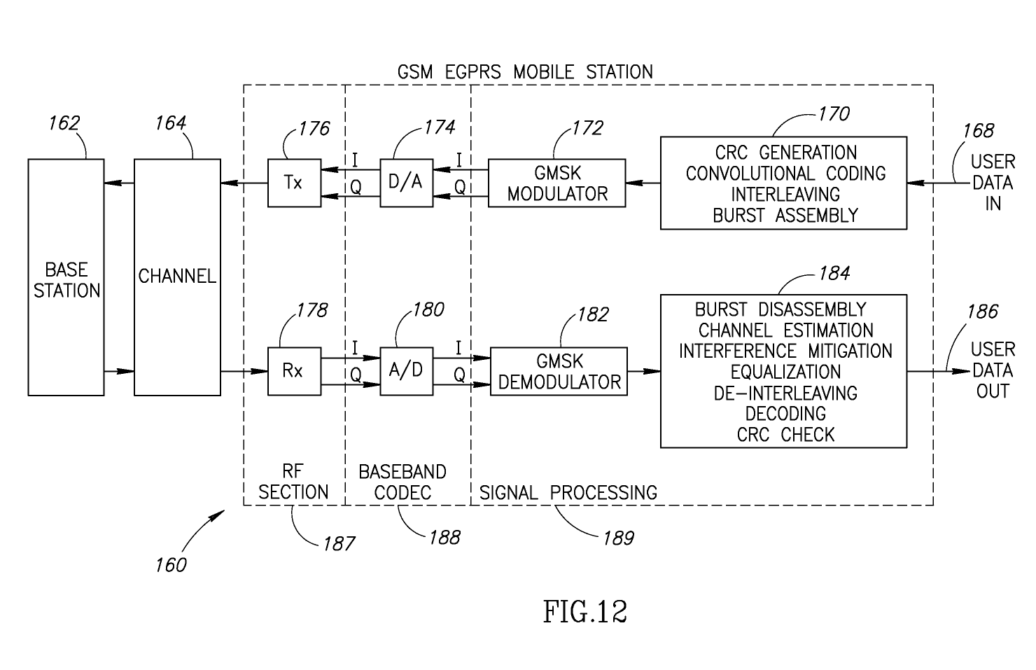

A GSM EGPRS mobile station constructed to implement the interference mitigation mechanism of the present invention is presented. A block diagram illustrating the processing blocks of a GSM EGPRS mobile station in more detail including RF, baseband and signal processing blocks is shown in FIG. 12. The radio station is designed to provide reliable data communications at rates of up to 470 kbit/s. The GSM EGPRS mobile station, generally referenced 160, comprises a transmitter and receiver divided into the following sections: signal processing circuitry 187, baseband codec 188 and RF circuitry section 189.

In the transmit direction, the signal processing portion functions to protect the data so as to provide reliable communications from the transmitter to the base station 162 over the channel 164. Several processes performed by the channel coding block 170 are used to protect the user data 168 including cyclic redundancy code (CRC) check, convolutional coding, interleaving and burst assembly. The resultant data is assembled into bursts whereby guard and trail symbols are added in addition to a training sequence midamble that is added to the middle of the burst. Note that both the user data and the signaling information go through similar processing. The assembled burst is then modulated by a modulator 172 which may be implemented as a π/2 GMSK modulator.

In the receive direction, the output of the baseband codec is demodulated using a complementary 8PSK demodulator 182. Several processes performed by the channel decoding block 184 in the signal processing section are then applied to the demodulated output. The processes performed include burst disassembly, channel estimation, interference mitigation utilizing the interference mitigation mechanism as taught by the present invention, described in detail supra, equalization, de-interleaving, convolutional decoding and CRC check. Optionally, soft value generation utilizing the modified metric as taught by the present invention and soft symbol to soft bit conversion may also be performed depending on the particular implementation.

The baseband codec converts the transmit and receive data into analog and digital signals, respectively, via D/A converter 174 and A/D converter 180. The transmit D/A converter provides analog baseband I and Q signals to the transmitter 176 in the RF circuitry section. The I and Q signals are used to modulate the carrier for transmission over the channel.

In the receive direction, the signal transmitted by the base station over the channel is received by the receiver circuitry 178. The analog signals I and Q output from the receiver are converted back into a digital data stream via the A/D converter. This I and Q digital data stream is filtered and demodulated by the GMSK demodulator 182 before being input to the channel decoding block 184. Several processes performed by signal processing block are then applied to the demodulated output.

In addition, the mobile station performs other functions that may be considered higher level such as synchronization, frequency and time acquisition and tracking, monitoring, measurements of received signal strength and control of the radio. Other functions include handling the user interface, signaling between the mobile station and the network, the SIM interface, etc.

### Computer Embodiment

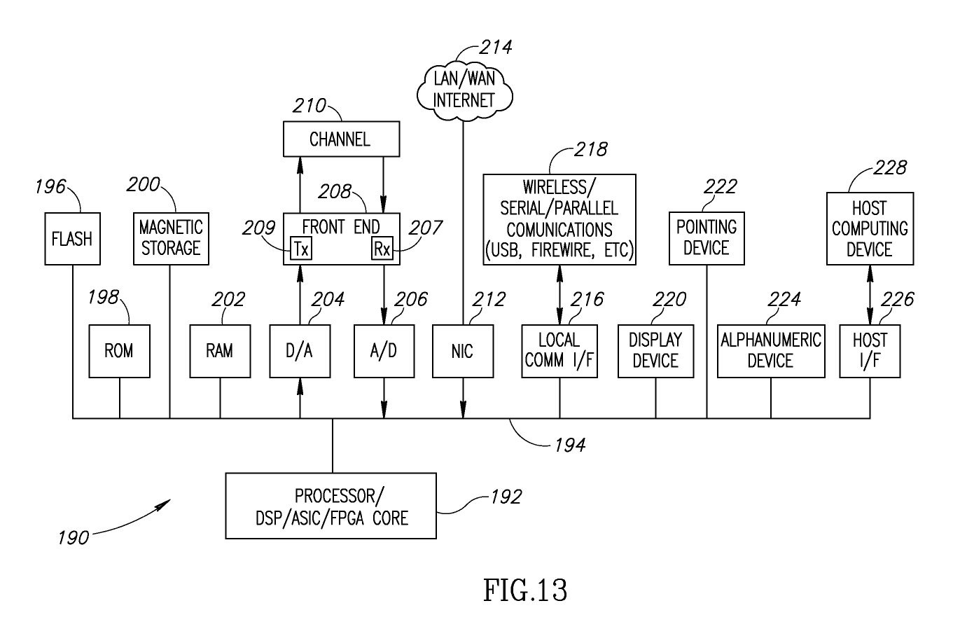

In alternative embodiments, the present invention may be applicable to implementations of the invention in integrated circuits or chip sets, wired or wireless implementations, switching system products and transmission system products. For example, a computer is operative to execute software adapted to implement the interference mitigation mechanism of the present invention. A block diagram illustrating an example computer processing system adapted to perform the interference mitigation mechanism of the present invention is shown in FIG. 13. The system may be incorporated within a communications device such as a receiver or transceiver, some or all of which may be implemented in software, hardware or a combination of software and hardware.

The computer system, generally referenced 190, comprises a processor 192 which may include a digital signal processor (DSP), central processing unit (CPU), microcontroller, microprocessor, microcomputer, ASIC or FPGA core. The system also comprises static read only memory 198, Flash memory 196 and dynamic main memory (RAM) 202 all in communication with the processor via bus 194. The processor is also in communication with a number of peripheral devices that are also included in the computer system. Peripheral devices coupled to the bus include a display device 220 (e.g., monitor), alpha-numeric input device 224 (e.g., keyboard) and pointing device 222 (e.g., mouse, tablet, etc.)

In the receive direction, signals received over the channel 210 are first input to the RF front end circuitry 208 which comprises a receiver section 207 and a transmitter section 209. Baseband samples of the received signal are generated by the A/D converter 206 and read by the processor. Baseband samples generated by the processor are converted to analog by D/A converter 204 before being input to the transmitter for transmission over the channel via the RF front end.

The computer system is connected to one or more external networks such as a LAN or WAN 214 via communication lines connected to the system via a network interface card (NIC) 212. A local communications I/F port(s) 216 provides connections to various wireless and wired links and serial and parallel devices 218. Examples include peripherals (e.g., printers, scanners, etc.), wireless links (e.g., Bluetooth, UWB, WiMedia, WiMAX, etc.) and wired links (e.g., USB, Firewire, etc.) The network adapters and local communications I/F port(s) coupled to the system enable the data processing system to become coupled to other data processing systems or remote printers or storage devices through intervening private or public networks. Modems, cable modem and Ethernet cards are just a few of the currently available types of network adapters.

A host interface 226 connects a host device 228 to the system. The host is adapted to configure, control and maintain the operation of the system. The system also comprises magnetic or semiconductor based storage device 200 for storing application programs and data. The system comprises computer readable storage medium that may include any suitable memory means, including but not limited to, magnetic storage, optical storage, semiconductor volatile or non-volatile memory, biological memory devices, or any other memory storage device.

Software adapted to implement the interference mitigation mechanism of the present invention is adapted to reside on a computer readable medium, such as a magnetic disk within a disk drive unit. Alternatively, the computer readable medium may comprise a floppy disk, removable hard disk, Flash memory card, EEROM based memory, bubble memory storage, ROM storage, distribution media, intermediate storage media, execution memory of a computer, and any other medium or device capable of storing for later reading by a computer a computer program implementing the method of this invention. The software adapted to implement the interference mitigation mechanism of the present invention may also reside, in whole or in part, in the static or dynamic main memories or in firmware within the processor of the computer system (i.e. within microcontroller, microprocessor or microcomputer internal memory).

In alternative embodiments, the interference mitigation mechanism of the present invention may be applicable to implementations of the invention in integrated circuits, field programmable gate arrays (FPGAs), chip sets or application specific integrated circuits (ASICs), wired or wireless implementations and other communication system products.

Other digital computer system configurations can also be employed to perform the interference mitigation mechanism of the present invention, and to the extent that a particular system configuration is capable of performing the method of this invention, it is equivalent to the representative digital computer system of FIG. 13 and within the spirit and scope of this invention.

Once they are programmed to perform particular functions pursuant to instructions from program software that implements the method of this invention, such digital computer systems in effect become special purpose computers particular to the method of this invention. The techniques necessary for this are well-known to those skilled in the art of computer systems.

It is noted that computer programs implementing the method of this invention will commonly be distributed to users on a distribution medium such as floppy disk or CD-ROM or may be downloaded over a network such as the Internet using FTP, HTTP, or other suitable protocols. From there, they will often be copied to a hard disk or a similar intermediate storage medium.

When the programs are to be run, they will be loaded either from their distribution medium or their intermediate storage medium into the execution memory of the computer, configuring the computer to act in accordance with the method of this invention. All these operations are well-known to those skilled in the art of computer systems.

The mechanism of the present invention thus presents a new framework for addressing the problem of GMSK signal reception in the presence of ISI and co-channel interference. In the general case of the received signal comprising the output of an antenna array and/or an over sampled signal, the mechanism of the invention comprises a MIMO filter combined with an MLSE Forney equalizer. The mechanism, however, also comprises the case of a cascaded MISO filter structure resembling a maximal ratio combining (MRC) element followed by an Ungerboeck MLSE equalizer. Although this alternative embodiment of the invention is equivalent to the Forney equalizer based solution, in terms of algorithm performance, the implementation complexity is decreased considerably. Therefore, the mechanism presented results in a receiver structure most suitable for a generalized GMSK DARP receiver having relatively low complexity and without a loss in performance. Moreover, the efficiency of the mechanism increases as the dimension of the received signal increases.

Single antenna interference cancellation with no time over-sampling is employed for the purpose of performance and complexity analysis. The mechanism exhibits a gain of more than 1.2 dB for all DARP test cases wherein only a few testing points experience a performance margin of less than 4 dB.

Note that the GMSK SAIC based interference mitigation mechanism of the present invention is highly efficient in terms of algorithm complexity. Furthermore, the mechanism permits the elimination of several estimation processes required by conventional receivers. This reduction in required processing reflects an additional increase in receiver efficiency.

It is intended that the appended claims cover all such features and advantages of the invention that fall within the spirit and scope of the present invention. As numerous modifications and changes will readily occur to those skilled in the art, it is intended that the invention not be limited to the limited number of embodiments described herein. Accordingly, it will be appreciated that all suitable variations, modifications and equivalents may be resorted to, falling within the spirit and scope of the present invention.

What is claimed is:

1. An apparatus for interference mitigation in a digital receiver, comprising:
a multiple input multiple output (MIMO) filter operative to generate a plurality D of diversity branches as a function of a spatially diverse input signal and a plurality of parameter vectors, each parameter vector associated with one of said diversity branches; and
a parameter calculation module operative to generate said plurality of parameter vectors against an optimization criterion having predetermined constraints.

2. The apparatus according to claim 1, wherein said parameter calculation module is operative to generate said plurality of parameter vectors as a function of a known training sequence and received training samples.

3. The apparatus according to claim 1, wherein said optimization criterion comprises maximizing a sum of the signal to noise ratios (SNRs) of each said diversity branch.

4. The apparatus according to claim 1, wherein said D diversity branches are generated from a real constellation derived from I and Q data samples.

5. The apparatus according to claim 1, wherein said D diversity branches are generated from a real constellation derived from over sampling a received signal.

6. The apparatus according to claim 1, wherein said D diversity branches are generated from a real constellation derived from signals received from multiple antennas.

7. The apparatus according to claim 1, wherein said D diversity branches are generated from a complex constellation derived from over sampling a received signal.

8. The apparatus according to claim 1, wherein said D diversity branches are generated from a complex constellation derived from signals received from a multiple antennas.

9. The apparatus according to claim 1, wherein said parameter calculation module comprises means for determining a joint solution to said MIMO filter and said channel impulse response.

10. An apparatus for interference mitigation in a digital receiver, comprising:
a multiple input multiple output (MIMO) filter operative to generate a plurality D of diversity branches as a function of a spatially diverse input signal and a plurality of parameter vectors, each parameter vector associated with one of said diversity branches;
a parameter calculation module operative to generate said plurality of parameter vectors against an optimization criterion having predetermined constraints; and
a diversity combiner operative to combine said D diversity branches into a single branch.

11. The apparatus according to claim 10, wherein said parameter calculation module is operative to generate said plurality of parameter vectors as a function of a known training sequence and received training samples.

12. The apparatus according to claim 10, wherein said optimization criterion comprises maximizing a sum of the signal to noise ratios (SNRs) of each said diversity branch.

13. The apparatus according to claim 10, wherein said D diversity branches are generated from a real constellation derived from I and Q data samples.

14. The apparatus according to claim 10, wherein said D diversity branches are generated from a real constellation derived from over sampling a received signal.

15. The apparatus according to claim 10, wherein said D diversity branches are generated from a real constellation derived from signals received from a multiple antennas.

16. The apparatus according to claim 10, wherein said D diversity branches are generated from a complex constellation derived from over sampling a received signal.

17. The apparatus according to claim 10, wherein said D diversity branches are generated from a complex constellation derived from signals received from multiple antennas.

18. The apparatus according to claim 10, wherein said MIMO filter and said diversity combiner jointly comprise a multiple input single output (MISO) filter.

19. The apparatus according to claim 10, wherein said diversity combiner comprises means for selective combining of said D diversity branches.

20. The apparatus according to claim 10, wherein said diversity combiner comprises means for factoring said D diversity branches with corresponding D channel impulse responses into a single channel impulse response and single output branch.

21. The apparatus according to claim 10, wherein said diversity combiner comprises means for suboptimal combining.

22. The apparatus according to claim 10, wherein said diversity combiner comprises a maximal ratio combining (MRC) filter structure that functions as an MRC element.

23. The apparatus according to claim 10, wherein said parameter calculation module comprises means for determining a joint solution to said MIMO filter and said channel impulse response.

24. An apparatus for interference mitigation in a digital receiver, comprising:
a multiple input multiple output (MIMO) filter operative to generate a plurality D of diversity branches as a function of a spatially diverse input signal and a plurality of parameter vectors, each parameter vector associated with one of said diversity branches;
a parameter calculation module operative to generate said plurality of parameter vectors against an optimization criterion having predetermined constraints; and
a spatial equalizer operative to generate a plurality of soft values as a function of said plurality D of diversity branches.

25. An apparatus for interference mitigation in a digital receiver, comprising:
a multiple input multiple output (MIMO) filter operative to generate a plurality D of diversity branches as a function of a spatially diverse input signal and a plurality of parameter vectors, each parameter vector associated with one of said diversity branches;
a parameter calculation module operative to generate said plurality of parameter vectors against an optimization criterion having predetermined constraints, and to generate a channel impulse response for each said diversity branch;
a diversity combiner operative to combine said D diversity branches into a single branch and to combine said D channel impulse responses into a single channel impulse response; and
an equalizer operative to remove intersymbol interference introduced by said channel from said single branch and to generate a plurality of soft values therefrom.

26. The apparatus according to claim 25, wherein said equalizer comprises an Ungerboeck equalizer.

27. The apparatus according to claim 25, further comprising:
a whitening matched filter coupled to the output of said diversity combiner; and
wherein said equalizer comprises a Forney equalizer coupled to the output of said whitening matched filter.

28. The apparatus according to claim 25, wherein said equalizer comprises an equalizer selected from the group consisting of DDFSE, DFE, RSSE, MMSE.

29. The apparatus according to claim 25, wherein said equalizer comprises a slicer.

30. A computer program product characterized by that upon loading it into computer memory an interference mitigation process is executed, said computer program product comprising:
a computer usable medium having computer usable program code for mitigating interference in a digital receiver, said computer program product including;
computer usable program code for implementing a multiple input multiple output (MIMO) filter operative to generate a plurality D of diversity branches as a function of a spatially diverse input signal and a plurality of parameter vectors, each parameter vector associated with one of said diversity branches;
computer usable program code for generating said plurality of parameter vectors against an optimization criterion having predetermined constraints; and
computer usable program code for implementing a diversity combiner operative to combine said D diversity branches into a single branch.

31. A radio receiver coupled to a single antenna, comprising:
a radio frequency (RF) receiver front end circuit for receiving a radio signal transmitted over a channel and downconverting the received radio signal to a baseband signal, said received radio signal comprising an information component and an interference component;
a demodulator adapted to demodulate said baseband signal in accordance with the modulation scheme used to generate said transmitted radio signal;
an interference mitigation module, comprising:
a multiple input multiple output (MIMO) filter operative to generate a plurality D of diversity branches as a function of a spatially diverse input signal and a plurality of parameter vectors, each parameter vector associated with one of said diversity branches;
a parameter calculation module operative to generate said plurality of parameter vectors and to generate said plurality of channel impulse responses corresponding to each said diversity branch against an optimization criterion having predetermined constraints;
a diversity combiner operative to combine said D diversity branches into a single branch and to combine said D channel impulse responses into a single channel impulse response;
an equalizer adapted to remove intersymbol interference introduced by said channel impulse response from said single branch and to generate a plurality of soft values therefrom; and
a decoder adapted to decode the output of said equalizer to generate output data therefrom.
